(19) United States
(12) Patent Application Publication
(10) Pub. No.: US 2024/0235488 A1
(43) Pub. Date: Jul. 11, 2024

(54) POWER AMPLIFIER CIRCUIT

(71) Applicant: Murata Manufacturing Co., Ltd., Kyoto (JP)

(72) Inventors: Satoshi TANAKA, Kyoto (JP); Yuri HONDA, Kyoto (JP); Hideyuki SATO, Kyoto (JP)

(21) Appl. No.: 18/403,131

(22) Filed: Jan. 3, 2024

(30) Foreign Application Priority Data
Jan. 5, 2023 (JP) 2023-000731

(51) Int. Cl. H03F 1/02; H03F 1/56; H03F 3/21

(52) U.S. Cl. CPC H03F 1/0288; H03F 1/56; H03F 3/211; H03F 2200/387

(57) ABSTRACT

A power amplifier circuit includes: a first amplifier; a second amplifier; and an impedance inverter that delays an output of the first amplifier by a time equivalent to ¼ of a wavelength of a transmission line, and combines the output of the first amplifier delayed by the impedance inverter and an output of the second amplifier and outputs a combined output. The impedance inverter includes a plurality of unit circuits each constituted by an inductor and a capacitor, the plurality of unit circuits are cascade-connected to an output side of the first amplifier, an element included in each unit circuit of the plurality of unit circuits is connected in series to the element of an adjacent unit circuit, and another element included in each unit circuit of the plurality of unit circuits is connected between one end of the element of the same unit circuit.

### CROSS REFERENCE TO RELATED APPLICATION

This application claims priority from Japanese Patent Application No. 2023-000731 filed on Jan. 5, 2023. The content of this application is incorporated herein by reference in its entirety.

### BACKGROUND ART

The present disclosure relates to a power amplifier circuit.

To increase communication speeds of mobile communication typically performed over mobile phone networks, modulated signals increasingly become multivalued. This leads to an increase in the PAPR (peak-to-average power ratio) of modulated signals. To cope with this increase, a Doherty power amplifier circuit is often used as a power amplifier (which may be hereinafter referred to as PA) for mobile phones (for example, Japanese Unexamined Patent Application Publication No. 2009-239882). The Doherty power amplifier circuit is known as a PA that attains a high efficiency even in a state in which the output power drops from the maximum output power by a predetermined amount. Japanese Unexamined Patent Application Publication No. 2009-239882 describes a Doherty power amplifier circuit that includes a carrier amplifier and a peak amplifier. On the output side of the carrier amplifier, a λ/4 wavelength transmission line is provided. In the following description, one wavelength is expressed by “λ”.

In mobile phone networks, as the transmission band has a wider bandwidth, the bandwidths of corresponding bands are also becoming wider. Therefore, making the bandwidths of power amplifiers wider, that is, attaining a wider bandwidth, is an issue. To attain a wider bandwidth, a technique in which a π-type impedance inverter is provided on the output side of the carrier amplifier is known (for example, M. Pashaeifar, A. K. Kumaran, M. Beikmirza, L. C. N. de Vreede, and M. S. Alavi, “A 24-to-32 GHz series-Doherty PA with two-step impedance inverting power combiner achieving 20.4 dBm Psat and 38%/34% PAE at Psat/6 dB PBO for 5G applications”, IEEE Asian Solid-State Circuits Conference (A-SSCC), pp. 1-3, November 2021).

### BRIEF SUMMARY

In the power amplifier circuits according to Japanese Unexamined Patent Application Publication No. 2009-239882 and M. Pashaeifar, A. K. Kumaran, M. Beikmirza, L. C. N. de Vreede, and M. S. Alavi, “A 24-to-32 GHz series-Doherty PA with two-step impedance inverting power combiner achieving 20.4 dBm Psat and 388/34% PAE at Psat/6 dB PBO for 5G applications”, IEEE Asian Solid-State Circuits Conference (A-SSCC), pp. 1-3, November 2021 mentioned above, the band of the impedance inverter might not be sufficient, and the bandwidth is likely to be insufficient.

The present disclosure provides a power amplifier circuit that can attain a wider bandwidth.

A power amplifier circuit according to an aspect of the present disclosure is a power amplifier circuit including: a first amplifier; a second amplifier; and an impedance inverter that delays an output of the first amplifier by a time equivalent to ¼ of a wavelength of a transmission line, the power amplifier circuit combining the output of the first amplifier delayed by the impedance inverter and an output of the second amplifier and outputting a combined output, in which the impedance inverter includes a plurality of unit circuits each constituted by an inductor and a capacitor, the plurality of unit circuits are cascade-connected to an output side of the first amplifier, and when one of the inductor and the capacitor is defined as a first element and the other is defined as a second element, the first element included in each unit circuit of the plurality of unit circuits is connected in series to the first element of an adjacent unit circuit, and the second element included in each unit circuit of the plurality of unit circuits is connected between one end of the first element of the same unit circuit, the one end being an end closer to the first amplifier, and a reference potential.

A power amplifier circuit according to another aspect of the present disclosure is a power amplifier circuit including: a first amplifier; a second amplifier; and an impedance inverter that delays an output of the first amplifier by a time equivalent to ¼ of a wavelength of a transmission line, the power amplifier circuit combining the output of the first amplifier delayed by the impedance inverter and an output of the second amplifier and outputting a combined output, in which the first amplifier and the second amplifier each includes a pair of amplifier elements that differentially operate, the impedance inverter includes a plurality of unit circuits each including an inductor and a capacitor, the plurality of unit circuits are cascade-connected to an output side of the first amplifier, and when one of the inductor and the capacitor is defined as a first element and the other is defined as a second element, each unit circuit includes a pair of first elements so as to correspond to the pair of amplifier elements, the pair of first elements included in each unit circuit of the plurality of unit circuits are connected in series to the pair of first elements included in an adjacent unit circuit, and the second element included in each unit circuit of the plurality of unit circuits is connected between one end of one first element of the pair of first elements included in the same unit circuit and one end of the other first element of the pair of first elements included in the same unit circuit, each one end being an end closer to the first amplifier.

According to the present disclosure, a wider bandwidth can be attained in a power amplifier circuit.

### BRIEF DESCRIPTION OF THE DRAWINGS

FIG. 1 is a diagram illustrating a power amplifier circuit according to a comparative example;

FIG. 2 is a diagram illustrating an equivalent circuit of the power amplifier circuit in FIG. 1;

FIG. 3 is a Smith chart for explaining a function of an impedance inverter;

FIG. 4 is a diagram illustrating changes in the impedance on the load side of a carrier amplifier and in the impedance on the load side of a peak amplifier;

FIG. 5 is a diagram for explaining the timing at which the peak amplifier is made to start operating;

FIG. 6 is a circuit diagram illustrating an example π-type impedance inverter;

FIG. 7 is a circuit diagram illustrating another example π-type impedance inverter;

FIG. 8 is a Smith chart illustrating the locus of the impedance of the two-stage π-type impedance inverter illustrated in FIG. 7;

FIG. 9 is a diagram illustrating a configuration of a power amplifier circuit according to a first embodiment of the present disclosure;

FIG. 10 is a diagram illustrating an equivalent circuit of the power amplifier circuit in FIG. 9 while focusing on an impedance inverter;

FIG. 11 is a Smith chart for explaining a function of the impedance inverter used in the power amplifier circuit according to the first embodiment;

FIG. 12 is a diagram for explaining a symmetrical impedance inverter and an asymmetrical impedance inverter by comparing their VSWR characteristics;

FIG. 13 is a diagram illustrating an impedance inverter used in a power amplifier circuit according to a second embodiment;

FIG. 14 is a diagram illustrating an impedance inverter used in a power amplifier circuit according to a third embodiment;

FIG. 15 is a diagram illustrating an impedance inverter used in a power amplifier circuit according to a fourth embodiment;

FIG. 16 is a diagram illustrating an impedance inverter used in a power amplifier circuit according to a fifth embodiment;

FIG. 17 is a diagram illustrating a power amplifier circuit according to a sixth embodiment of the present disclosure;

FIG. 18 is a diagram illustrating a power amplifier circuit according to a seventh embodiment of the present disclosure;

FIG. 19 is a diagram illustrating a power amplifier circuit according to an eighth embodiment of the present disclosure; and

FIG. 20 is a diagram illustrating a power amplifier circuit according to a ninth embodiment of the present disclosure.

### DETAILED DESCRIPTION

Hereinafter, embodiments of the present disclosure will be described in detail with reference to the drawings. In the following description of each embodiment, a part of a configuration the same as or equivalent to that in any other embodiment is assigned the same reference numeral, and a description thereof will be briefly given or omitted. Each embodiment is not intended to limit the present disclosure. Some of the constituent elements in each embodiment are replaceable by a person skilled in the art and easy or are substantially identical. Note that configurations described below can be combined as appropriate. Furthermore, configurations can be omitted, replaced, or changed without necessarily departing from the gist of the present disclosure.

To facilitate understanding of embodiments, a comparative example will first be described below.

### COMPARATIVE EXAMPLE

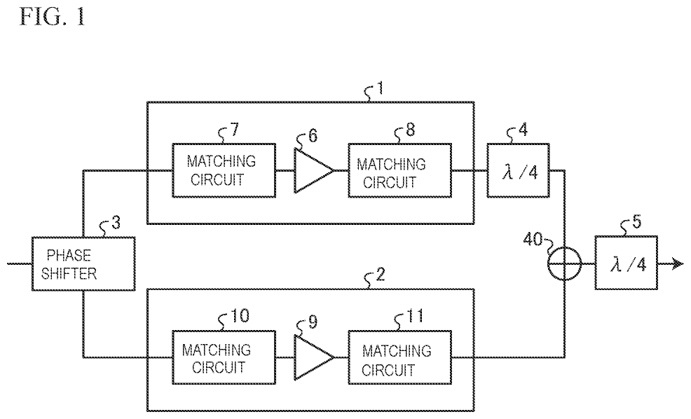

FIG. 1 is a diagram illustrating a power amplifier circuit according to a comparative example. The power amplifier circuit illustrated in FIG. 1 includes a carrier amplifier 1, which is a first amplifier, a peak amplifier 2, which is a second amplifier, a phase shifter 3, an impedance inverter 4, a combiner 40, and a matching circuit 5. The power amplifier circuit illustrated in FIG. 1 has functions of a Doherty power amplifier circuit. That is, one of the carrier amplifier 1 and the peak amplifier 2 that constitute the Doherty amplifier circuit is the first amplifier and the other is the second amplifier.

The phase shifter 3 is an input phase shifter that delays the phase of an input signal that is input to the peak amplifier 2 by 90 degrees. Note that the phase delayed by the phase shifter 3 is a time equivalent to ¼ of the wavelength of the transmission line and needs to be approximately 90 degrees (45 degrees or more and 135 degrees or less). The carrier amplifier 1 includes an amplifier circuit 6, a matching circuit 7 on the input side, and a matching circuit 8 on the output side. The peak amplifier 2 includes an amplifier circuit 9, a matching circuit 10 on the input side, and a matching circuit 11 on the output side. The amplifier circuits 6 and 9 each includes a transistor that is an amplifier element amplifying power. Although each transistor is a bipolar transistor in the present disclosure, the present disclosure is not limited to this. Although the bipolar transistor is, for example, a heterojunction bipolar transistor (HBT), the present disclosure is not limited to this. Each transistor may be, for example, a field-effect transistor (FET).

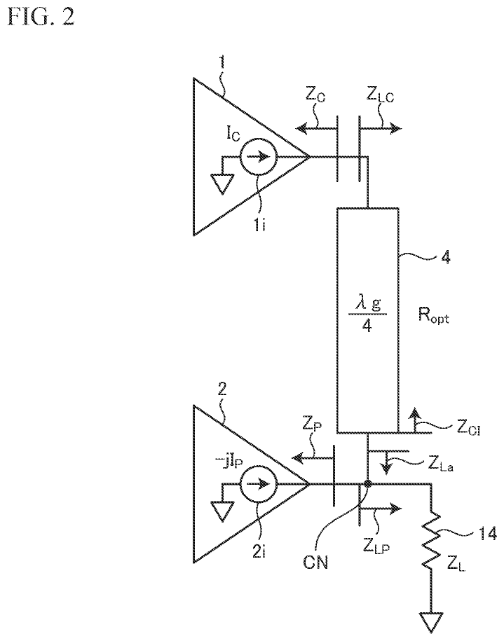

The impedance inverter 4 appropriately changes the impedance on the load side of the carrier amplifier 1 in accordance with the operating state of the peak amplifier 2. The combiner 40 combines an output of the carrier amplifier 1 having passed through the impedance inverter 4 and an output of the peak amplifier 2. A connecting node CN (see FIG. 2) that connects signal lines with each other and that combines the currents together corresponds to the combiner 40. The matching circuit 5 is a matching circuit for performing matching for a transmission line on the output side of the combiner 40.

A description of how the impedance inverter 4 functions in the Doherty power amplifier circuit will be given below. FIG. 2 is a diagram illustrating an equivalent circuit of the power amplifier circuit in FIG. 1. FIG. 2 illustrates the carrier amplifier 1, the peak amplifier 2, and the impedance inverter 4. In FIG. 2, the carrier amplifier 1 and the peak amplifier 2 are illustrated as current sources 1i and 2i respectively to simplify the description. It is assumed that the phase of the output of the peak amplifier 2 is delayed from the phase of the output of the carrier amplifier 1 by 90 degrees.

A matching circuit 14 performs matching for an output of the entire power amplifier circuit. An impedance when the output side of the Doherty power amplifier circuit is seen from the connecting node CN connected with the output side of the carrier amplifier 1 and the output side of the peak amplifier 2 is denoted by Z_{L}. The value of the impedance Z_{L} is set to half of the characteristic impedance Rₒₚₜ of the impedance inverter 4, that is, Z_{L}=Rₒₚₜ/2.

It is often the case that in the Doherty power amplifier circuit, the carrier amplifier 1 is given a bias so as to perform a class AB operation and the peak amplifier 2 is given a bias so as to perform a class C operation. In this example, the biases are also set as described above. Accordingly, the bias current of the carrier amplifier 1 is increased relative to the peak amplifier 2 to operate the carrier amplifier 1. Therefore, when an input signal is small, only the carrier amplifier 1 operates and the peak amplifier 2 does not operate. In this case, because of the impedance being equal to Z_{L}=Rₒₚₜ/2, a function of the impedance inverter 4 makes an impedance on the load side of the carrier amplifier 1 be equal to Z_{LC}=2Rₒₚₜ.

In FIG. 2, an impedance on the load side of the impedance inverter 4 when seen from the carrier amplifier 1 is denoted by Z_{LC}, and an impedance when the side adjacent to the connecting node CN connected with the peak amplifier 2 is seen from the impedance inverter 4 is denoted by Z_{La}.

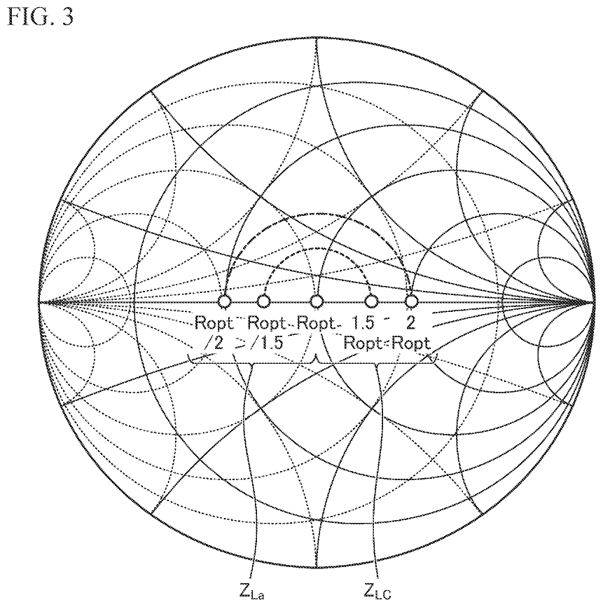

The function of the impedance inverter 4 will be described below. FIG. 3 is a Smith chart for explaining the function of the impedance inverter 4.

As described above, the impedance inverter 4 is formed of a λ/4 transmission line having a characteristic impedance equal to Rₒₚₜ. An impedance of the impedance inverter 4 on the load side of the carrier amplifier 1 is denoted by Z_{LC}, and an impedance, on the load side adjacent to the connecting node CN connected with the peak amplifier 2, seen from the impedance inverter 4 is denoted by Z_{La}. When the peak amplifier 2 does not operate, that is, when the output current I_{P} of the peak amplifier 2 is 0, the impedance Z_{La} and the impedance Z_{L} have the same values. That is, the connecting node side of the impedance inverter 4 is terminated with the impedance Rₒₚₜ/2. This is converted by the impedance inverter 4 as depicted by the dashed dotted line in FIG. 3 to 2Rₒₚₜ, resulting in Z_{LC}=2Rₒₚₜ. When the connecting node side of the impedance inverter 4 is terminated with an impedance Rₒₚₜ/1.5, the impedance is converted by the impedance inverter 4 as depicted by the dashed line in FIG. 3 to 1.5Rₒₚₜ, resulting in Z_{LC}=1.5Rₒₚₜ.

In FIG. 2, the carrier amplifier 1 is illustrated as the current source 1i, and the output impedance of the carrier amplifier 1 becomes Z_{C}=∞. In this case, when an impedance on the connecting node CN side of the impedance inverter 4 is denoted by Z_{CI}, Z_{CI}=0 holds, and the impedance inverter 4 becomes equivalent to a voltage source.

When an input signal of the Doherty power amplifier circuit becomes large and the output current I_{P} of the peak amplifier 2 is generated, the current starts flowing into the impedance Z_{L}, and a voltage generated at the impedance Z_{L} increases. Taking into account an influence given by this, the impedance Z_{La} can be expressed by expression (1) below. That is, the following holds.

$${Z}_{L a} = {R}_{opt} ( {I}_{C} / ( 2 {I}_{C} - {I}_{P} ) ) \qquad ( 1 )$$

Therefore, the value of the impedance Z_{La} increases as the output current I_{P} increases. In this case, with the effect produced by the impedance inverter 4, the impedance Z_{LC} on the load side can be expressed by expression (2) below. That is, the following holds.

$${Z}_{L C} = {R}_{opt} ( ( 2 {I}_{C} - {I}_{P} ) / {I}_{C} ) \qquad ( 2 )$$

At the impedance inverter 4, the phase is delayed by 90 degrees. Therefore, the phase of the output of the peak amplifier 2 is delayed in advance by 90 degrees relative to the carrier amplifier 1. Accordingly, the operations described above are not affected by the phase. An impedance Z_{LP} on the load side when seen from the peak amplifier 2 can be expressed by expression (3) below. That is, the following holds.

$${Z}_{L P} = {R}_{opt} ( {I}_{C} / {I}_{P} ) \qquad ( 3 )$$

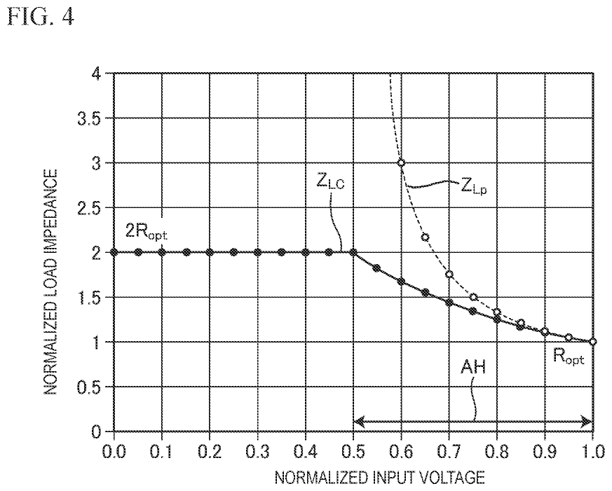

Changes in the impedance Z_{LC} on the load side of the carrier amplifier 1 and in the impedance Z_{LP} on the load side of the peak amplifier 2 caused by the series of operations described above will be described with reference to the drawings. FIG. 4 is a diagram illustrating changes in the impedance Z_{LC} on the load side of the carrier amplifier 1 and in the impedance Z_{LP} on the load side of the peak amplifier 2.

The horizontal axis in FIG. 4 represents a normalized input voltage obtained by normalizing the input signal while assuming the maximum input signal to be equal to 1. The vertical axis in FIG. 4 represents a normalized load impedance. As shown by FIG. 4, when the input signal is 0.5 or less, only the carrier amplifier 1 operates and the peak amplifier 2 does not operate. The impedance of the carrier amplifier 1 in this case is Z_{LC}=2Rₒₚₜ.

When the input signal exceeds 0.5, the peak amplifier 2 starts operating. The sign AH in FIG. 4 indicates the operation range of the peak amplifier. After the peak amplifier 2 starts operating, the impedance Z_{LC} gradually decreases and becomes equal to Z_{LC}=Rₒₚₜ at the maximum input signal level (=1). The impedance on the load side of the peak amplifier 2 before the peak amplifier 2 operates is equal to Z_{LP}=∞. As the peak amplifier 2 starts operating, the impedance on the load side decreases, and the impedance on the load side of the peak amplifier 2 becomes equal to Z_{LP}=Rₒₚₜ at the maximum input signal level (=1) similarly to the carrier amplifier 1.

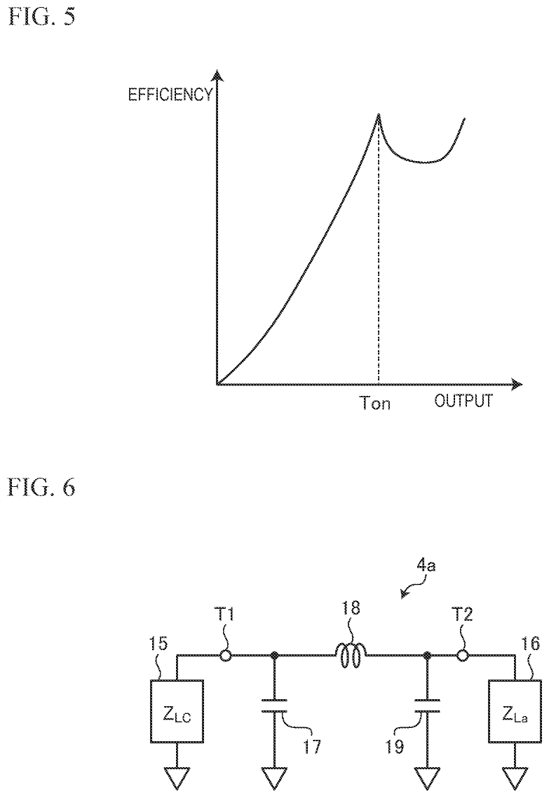

The timing at which the peak amplifier 2 is made to start operating will be described below. FIG. 5 is a diagram for explaining the timing at which the peak amplifier 2 is made to start operating. In FIG. 5, the horizontal axis represents the output of the amplifying circuit including the carrier amplifier 1 and the peak amplifier 2 and the vertical axis represents the operation efficiency of the amplifying circuit.

In FIG. 5, the peak amplifier 2 can be made to start operating at a timing Tₒₙ at which the output of the carrier amplifier 1 becomes large and the operation of the carrier amplifier 1 approaches a saturation operation. Accordingly, the output power of the peak amplifier 2 is added and the impedance on the load side of the carrier amplifier 1 is decreased to thereby output a larger power that increases the maximum output. Although a region in which the efficiency decreases after the peak amplifier 2 starts operating is present, the efficiency can be kept high. Therefore, a high-efficiency operation close to a saturation operation can be attained at a wide input level. This can improve the efficiency of the entire power amplifier circuit and attain a high-efficiency operation.

As described above, the Doherty power amplifier circuit can attain a high efficiency across a wide output power range. However, in a frequency band of 0.7 GHZ to 5.0 GHz used in mobile phone networks, the length of ¼ of a wavelength λ in a vacuum, that is, the length of a λ/4 wavelength, is about 1 m to 15 cm. Assuming that the transmission line is provided inside the housing of a mobile phone device, this λ/4 wavelength is too long even when the effect of wavelength reduction by a dielectric is taken into account. Therefore, it is often the case that a π-type impedance inverter is used instead of the λ/4 wavelength transmission line.

### Examples of λ-Type Impedance Inverter

FIG. 6 is a circuit diagram illustrating an example π-type impedance inverter. A π-type impedance inverter 4a illustrated in FIG. 6 includes terminals T1 and T2, capacitors 17 and 19, and an inductor 18. The inductor 18 is connected in series between the terminal T1 and the terminal T2. One end of the capacitor 17 is connected between the terminal T1 and the inductor 18. The other end of the capacitor 17 is connected to a reference potential. One end of the capacitor 19 is connected between the terminal T2 and the inductor 18. The other end of the capacitor 19 is connected to the reference potential. The reference potential is, for example, a ground potential. The same applies to the following description.

Here, the terminal T1 is assumed to be an input terminal and the terminal T2 is assumed to be an output terminal. The impedance value of an input impedance 15 connected to the terminal T1 is denoted by Z_{LC}. The impedance value of an output impedance 16 connected to the terminal T2 is denoted by Z_{La}.

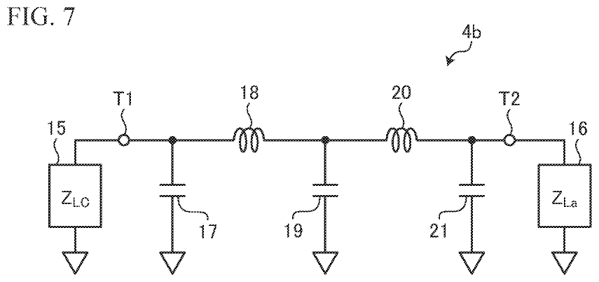

To attain a wider bandwidth in the power amplifier circuit, a technique in which a two-stage π-type impedance inverter is provided is known. FIG. 7 is a circuit diagram illustrating another example π-type impedance inverter. The π-type impedance inverter 4a illustrated in FIG. 6 is a one-stage π-type circuit. In contrast, a π-type impedance inverter 4b illustrated in FIG. 7 is a two-stage π-type circuit. That is, the π-type impedance inverter 4b illustrated in FIG. 7 has a configuration obtained by adding an inductor 20 and a capacitor 21 to the configuration illustrated in FIG. 6. The inductor 20 is connected in series between the inductor 18 and the terminal T2. One end of the capacitor 21 is connected between the terminal T2 and the inductor 20. The other end of the capacitor 21 is connected to the reference potential.

Focusing on FIG. 6, a configuration when the terminal T1 side is seen from the inductor 18 and a configuration when the terminal T2 side is seen from the inductor 18 are the same. Therefore, the impedance inverter 4a illustrated in FIG. 6 can be regarded as a symmetrical impedance inverter. Focusing on FIG. 7, a configuration when the terminal T1 side is seen from the capacitor 19 and a configuration when the terminal T2 side is seen from the capacitor 19 are the same. Therefore, the impedance inverter 4b illustrated in FIG. 7 can be regarded as a symmetrical impedance inverter.

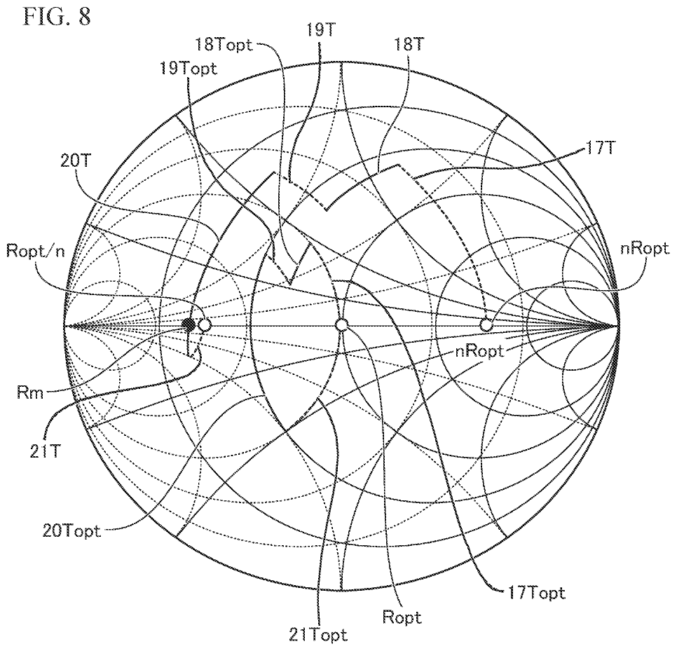

The operation of the two-stage π-type impedance inverter 4b illustrated in FIG. 7 will be described below. FIG. 8 is a Smith chart illustrating the locus of the impedance of the two-stage π-type impedance inverter 4b illustrated in FIG. 7.

In FIG. 8, first, the value of the impedance Z_{LC} on the input side of the impedance inverter 4b and the value of the impedance Z_{La} on the output side thereof are set to the characteristic impedance Rₒₚₜ of the impedance inverter. In this case, the impedance sequentially draws a locus 17Topt made by a capacitor 17, a locus 18Topt made by an inductor 18, a locus 19Topt made by a capacitor 19, a locus 20Topt made by an inductor 20, and a lotus 21Topt made by a capacitor 21 and returns to Rₒₚₜ.

Next, the value of the output impedance Z_{La} of the impedance inverter is set to 1/n (n is a positive number, the same applies hereinafter) of the characteristic impedance Rₒₚₜ of the impedance inverter. That is, the value is set to Rₒₚₜ/n. Then, the impedance reaches nRₒₚₜ through a locus 21T made by the capacitor 21, a locus 20T made by the inductor 20, a locus 19T made by the capacitor 19, a lotus 18T made by the inductor 18, and a locus 17T made by the capacitor 17. As described above, the impedance inverter having the characteristic impedance Rₒₚₜ is characterized in that when a load having an impedance Rₒₚₜ/n is connected to the output side, the impedance on the input side becomes nRₒₚₜ.

Focusing on FIG. 8 again, it is found that the locus 20T once runs across the real axis, and from a point of intersection Rm at which the locus 20T runs across, the impedance reaches Rₒₚₜ/n on the real axis closer to the center through a locus 21T. Such a locus is a combination of conversion from nRₒₚₜ to Rm and conversion from Rm to Rₒₚₜ/n, and the frequency band tends to become narrow.

### EMBODIMENTS

Embodiments will now be described.

### First Embodiment

### Configuration

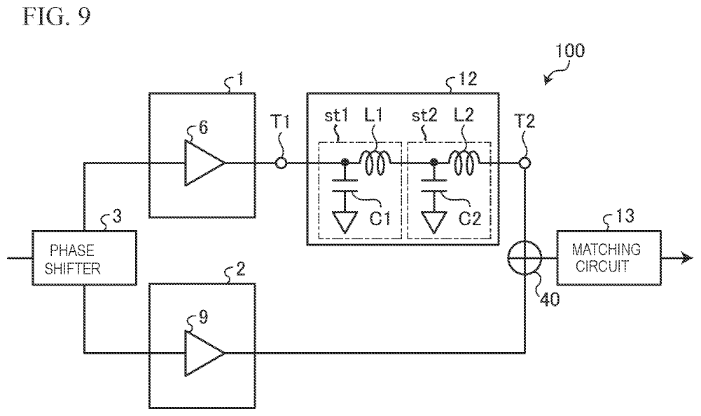

FIG. 9 is a diagram illustrating a configuration of a power amplifier circuit 100 according to a first embodiment of the present disclosure. In FIG. 9, the matching circuits in the carrier amplifier 1 and the matching circuits in the peak amplifier 2 are not illustrated. In this embodiment, an impedance inverter 12 is used instead of the impedance inverter 4 in FIG. 1. The impedance inverter 12 appropriately changes the impedance on the load side of the carrier amplifier 1 in accordance with the operating state of the peak amplifier 2. Instead of the matching circuit 5 in FIG. 1, a matching circuit 13 is used.

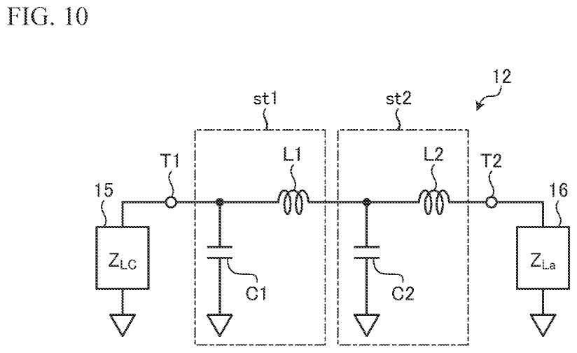

FIG. 10 is a diagram illustrating an equivalent circuit of the power amplifier circuit 100 in FIG. 9 while focusing on the impedance inverter 12. In FIG. 10, the value of the impedance of the input impedance 15 connected to the terminal T1 on the output side of the carrier amplifier 1 is denoted by Z_{LC}. The impedance value of the output impedance 16 connected to the terminal T2 adjacent to the connecting node connected with the carrier amplifier 1 and the peak amplifier 2 is denoted by Z_{La}.

The impedance inverter 12 includes a unit circuit st1 constituted by the inductor L1 and the capacitor C1 and a unit circuit st2 constituted by the inductor L2 and the capacitor C2. The two unit circuits, namely, the unit circuit st1 and the unit circuit st2, are cascade-connected between the terminal T1 on the input side and the terminal T2 on the output side. That is, the impedance inverter 12 includes the plurality of cascade-connected unit circuits, namely, the unit circuits st1 and st2. Cascade connection is a state of being connected such that a signal from the previous stage is input and the signal is output to the subsequent stage.

Focusing on the unit circuit st1, one end of the inductor L1 is connected to the terminal T1 on the input side. The other end of the inductor L1 is connected to one end of the inductor L2 of the unit circuit st2. One end of the capacitor C1 of the unit circuit st1 is connected between the inductor L1 and the terminal T1. The other end of the capacitor C1 is connected to the reference potential.

Focusing on the unit circuit st2, the one end of the inductor L2 is connected to the other end of the inductor L1. The other end of the inductor L2 is connected to the terminal T2 on the output side. One end of the capacitor C2 of the unit circuit st2 is connected between the inductor L1 and the inductor L2. The other end of the capacitor C2 is connected to the reference potential.

Focusing on the unit circuit st1, when one of the inductor and the capacitor of the unit circuit st1 is defined as a first element (in this example, the inductor L1) and the other is defined as a second element (in this example, the capacitor C1), the first element included in the unit circuit st1 is connected in series to a first element (in this example, the inductor L2) of the unit circuit st2, which is the adjacent unit circuit.

Furthermore, the second element included in the unit circuit st1 is connected between one end of the first element of the same unit circuit st1 and the reference potential. That is, the second element is connected between one end of the first element, the one end being an end closer to the carrier amplifier 1 (that is, the first amplifier), and the reference potential.

Focusing on the unit circuit st2, when one of the inductor and the capacitor of the unit circuit st2 is defined as a first element (in this example, the inductor L2) and the other is defined as a second element (in this example, the capacitor C2), the first element included in the unit circuit st2 is connected in series to a first element (in this example, the inductor L1) of the unit circuit st1, which is the adjacent unit circuit.

Furthermore, the second element included in the unit circuit st2 is connected between one end of the first element of the same unit circuit st2 and the reference potential.

The configuration of the impedance inverter 12 illustrated in FIG. 10 will now be compared with the configuration of the impedance inverter 4b illustrated in FIG. 7. The impedance inverter 12 can be considered to have a configuration obtained by removing one capacitor closest to the terminal T2 on the output side of the impedance inverter 4b.

Based on this consideration, it is suitable to remove a capacitor on a side on which the impedance is low. In the power amplifier circuit 100 of this embodiment, the impedance on the side adjacent to the connecting node connected with the peak amplifier 2 is lower than the impedance on the side connected to the carrier amplifier 1, and therefore, the capacitor closest to the terminal T2 adjacent to the connecting node needs to be removed. Removing the capacitor closest to the terminal T1 on the side connected to the carrier amplifier 1 does not attain a desired effect. Therefore, no capacitor is present on the side closest to the terminal T2 (that is, on the side farthest from the carrier amplifier 1) and the inductor L2 of the unit circuit st2 is directly connected to the terminal T2.

### Operations

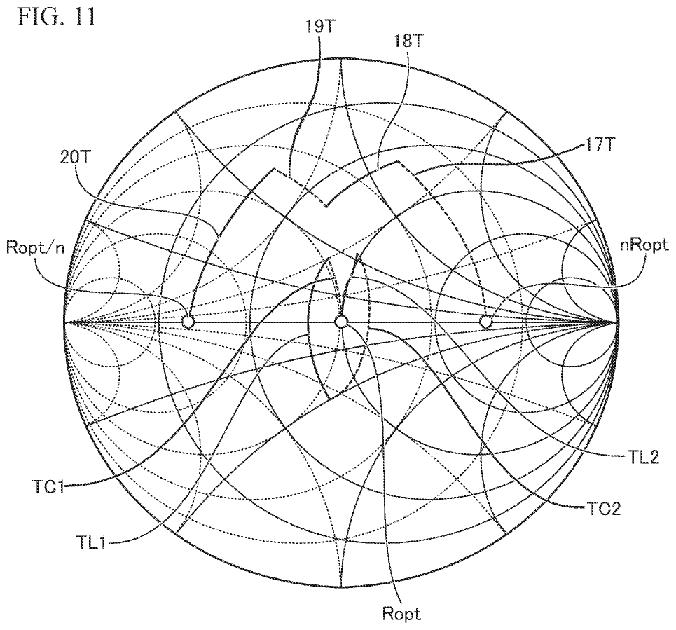

Operations of the impedance inverter 12 illustrated in FIG. 10 will now be described. FIG. 11 is a Smith chart for explaining a function of the impedance inverter 12 used in the power amplifier circuit according to the first embodiment.

First, the value of the impedance Z_{LC} on the input side of the impedance inverter and the value of the impedance Z_{La} on the output side thereof are set to the characteristic impedance Rₒₚₜ. In this case, as illustrated in FIG. 11, the impedance sequentially draws a locus TC1 made by the capacitor C1, a locus TL1 made by the inductor L1, a locus TC2 made by the capacitor C2, and a locus TL2 made by the inductor L2 and returns to the characteristic impedance Rₒₚₜ.

Next, the value of the output impedance Z_{La} is set to 1/n of the characteristic impedance Rₒₚₜ of the impedance inverter, that is, Rₒₚₜ/n. Then, the impedance reaches the impedance nRₒₚₜ through the locus 20T, the locus 19T, the locus 18T, and the locus 17T sequentially. As described above, in the impedance inverter having the characteristic impedance Rₒₚₜ, when a load of “Rₒₚₜ/n” is connected to the output side, the input side becomes “nRₒₚₜ”.

In FIG. 11, unlike in FIG. 8, it is found that the locus 20T does not run across the real axis, and the impedance directly reaches Rₒₚₜ/n on the real axis. Referring back to FIG. 8 again, it is found that the locus 20T once runs across the real axis, and subsequently, the impedance reaches Rₒₚₜ/n on the real axis through the locus 21T. It is found that the locus 21T reaches Rₒₚₜ/n on the real axis closer to the center from the point of intersection Rm at which the locus 20T runs across the real axis. Such a locus is a combination of conversion from nRₒₚₜ to the point of intersection Rm and conversion from the point of intersection Rm to Rₒₚₜ/n, and the frequency band tends to become narrow. To address this issue, an impedance inverter in which the topology between the input and output terminals is not symmetrical but asymmetrical as described above is used.

### Effects

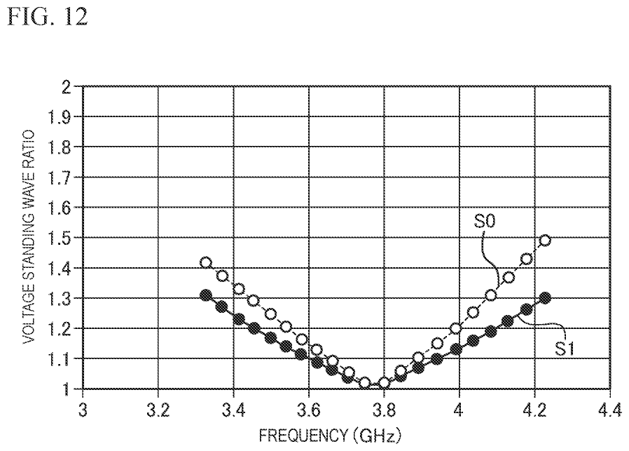

The voltage standing wave ratio characteristics (hereinafter referred to as VSWR characteristics) of a symmetrical impedance inverter and an asymmetrical impedance inverter will be described below. FIG. 12 is a diagram for explaining a symmetrical impedance inverter and an asymmetrical impedance inverter by comparing their VSWR characteristics. In FIG. 12, the horizontal axis represents the frequency (GHz) and the vertical axis represents the voltage standing wave ratio. The voltage standing wave ratio is “1” at minimum and can be closer to “1”.

In FIG. 12, the characteristic S0 is the VSWR (voltage standing wave ratio) characteristic when the symmetrical impedance inverter illustrated in FIG. 7 is seen from the terminal T1 on the input side. The characteristic S1 is the VSWR characteristic when seen from the terminal T1 on the input side of the asymmetrical impedance inverter 12 illustrated in FIG. 9 and FIG. 10.

With reference to FIG. 12, the characteristic S1 shows a VSWR closer to “1” than the characteristic so in a band from about 3.3 GHZ to a frequency exceeding 4.2 GHZ. Therefore, it is found that the asymmetrical impedance inverter 12 illustrated in FIG. 9 and FIG. 10 can attain a wider matching band than the symmetrical impedance inverter illustrated in FIG. 7.

### Second Embodiment

### Configuration

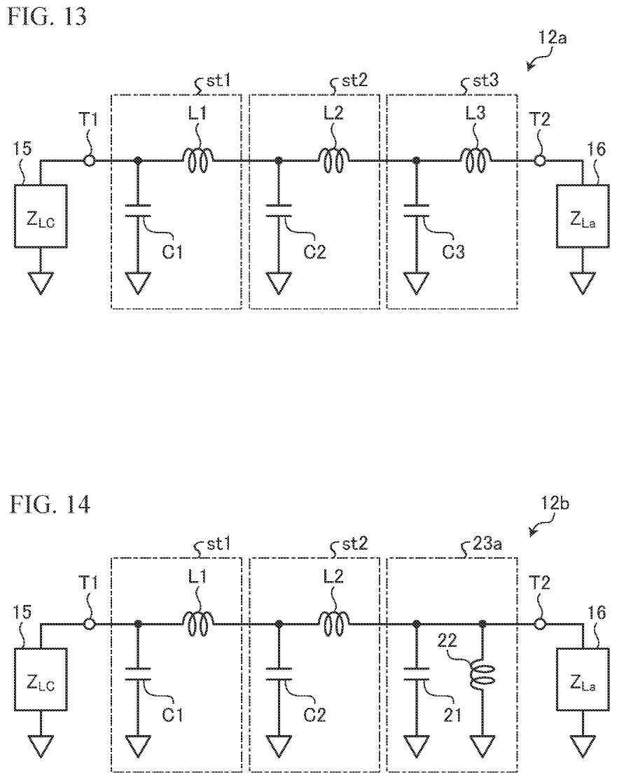

A power amplifier circuit according to a second embodiment of the present disclosure will now be described. In the power amplifier circuit according to the second embodiment of the present disclosure, the number of unit circuits in the impedance inverter in FIG. 10 is increased. FIG. 13 is a diagram illustrating an impedance inverter 12a used in the power amplifier circuit according to the second embodiment. The impedance inverter described with reference to FIG. 10 has a two-stage configuration including the unit circuits st1 and st2. In contrast, as illustrated in FIG. 13, the impedance inverter 12a used in the power amplifier circuit of this embodiment has a three-stage configuration including the unit circuits st1, st2, and st3.

In FIG. 13, the three unit circuits, namely, the unit circuits st1 to st3, are cascade-connected. The unit circuit st3 includes an inductor L3 and a capacitor C3. The inductor L3 of the unit circuit st3 is connected in series to the inductor L2 of the unit circuit st2. That is, one end of the inductor L3 is connected to the inductor L2. The other end of the inductor L3 is connected to the terminal T2. One end of the capacitor C3 of the unit circuit st3 is connected to a connecting node connected with the inductor L2 of the unit circuit st2 and the inductor L3. The other end of the capacitor C3 is connected to the reference potential.

Focusing on the unit circuit st1, when one of the inductor and the capacitor of the unit circuit st1 is defined as a first element (in this example, the inductor L1) and the other is defined as a second element (in this example, the capacitor C1), the first element included in the unit circuit st1 is connected in series to a first element (in this example, the inductor L2) of the unit circuit st2, which is the adjacent unit circuit.

Furthermore, the second element included in the unit circuit st1 is connected between one end of the first element of the same unit circuit st1 and the reference potential.

Focusing on the unit circuit st2, when one of the inductor and the capacitor of the unit circuit st2 is defined as a first element (in this example, the inductor L2) and the other is defined as a second element (in this example, the capacitor C2), the first element included in the unit circuit st2 is connected in series to a first element (in this example, the inductor L1) of the unit circuit st1, which is an adjacent unit circuit, and to a first element (in this example, the inductor L3) of the unit circuit st3, which is an adjacent circuit. Furthermore, the second element included in the unit circuit st2 is connected between one end of the first element of the same unit circuit st2 and the reference potential.

Similarly, focusing on the unit circuit st3, when one of the inductor and the capacitor of the unit circuit st3 is defined as a first element (in this example, the inductor L3) and the other is defined as a second element (in this example, the capacitor C3), the first element included in the unit circuit st3 is connected in series to a first element (in this example, the inductor L2) of the unit circuit st2, which is the adjacent unit circuit.

Furthermore, the second element included in the unit circuit st3 is connected between one end of the first element of the same unit circuit st3 and the reference potential.

Note that the impedance inverter 12a illustrated in FIG. 13 can be considered to have a configuration obtained by removing a capacitor on a side of a three-stage π-type circuit on which the impedance is low. That is, the configuration can be considered to be a configuration obtained by removing a capacitor closest to the terminal T2 on the output side from a three-stage π-type circuit.

### Operations

The asymmetrical impedance inverter 12a illustrated in FIG. 13 appropriately changes the impedance on the load side of the carrier amplifier 1 in accordance with the operating state of the peak amplifier 2. The impedance inverter 12a illustrated in FIG. 13 can attain matching characteristics represented by the locus described with reference to FIG. 11.

### Effects

Using the asymmetrical impedance inverter 12a according to this embodiment in the power amplifier circuit can attain a wider bandwidth in the power amplifier circuit.

### Third Embodiment

### Configuration

A power amplifier circuit according to a third embodiment of the present disclosure will now be described. In the power amplifier circuit according to the third embodiment of the present disclosure, a parallel resonance circuit is provided on the output side. FIG. 14 is a diagram illustrating an impedance inverter 12b used in the power amplifier circuit according to the third embodiment.

In FIG. 14, the two unit circuits, namely, the unit circuits st1 and st2, are cascade-connected. Furthermore, a parallel resonance circuit 23a is connected to the output side of the unit circuit st2. More specifically, the parallel resonance circuit 23a is connected between the inductor L2 of the unit circuit st2 and the terminal T2 on the output side. The parallel resonance circuit 23a includes the capacitor 21 and an inductor 22.

One end of the capacitor 21 is connected to a connecting node connected with the inductor L2 and the terminal T2. The other end of the capacitor 21 is connected to the reference potential. One end of the inductor 22 is connected to a connecting node connected with the inductor L2 and the terminal T2. The other end of the inductor 22 is connected to the reference potential. Therefore, the capacitor 21 and the inductor 22 are connected in parallel. Disposing the inductor 22 in parallel to the capacitor 21 can adjust the effect of the capacitor 21 in the impedance inverter 12b.

Note that the inductor 22 needs to be grounded in terms of AC. Therefore, the other end of the inductor 22 may be connected to a power supply Vcc terminal not illustrated. A DC cut capacitor having a large capacitance may be connected in series to the inductor 22.

### Operations

When the capacitor 21 and the inductor 22 enter a resonance state in the parallel resonance circuit 23a, this state appears to be a state in which the capacitor 21 or the inductor 22 is not connected. Therefore, when the capacitor 21 and the inductor 22 enter a resonance state, the impedance inverter 12b is in a state the same as the impedance inverter 12 illustrated in FIG. 10.

### Effects

Using the impedance inverter 12b according to this embodiment in the power amplifier circuit can attain a wider bandwidth in the power amplifier circuit.

### Fourth Embodiment

### Configuration

A power amplifier circuit according to a fourth embodiment of the present disclosure will now be described. The power amplifier circuit according to the fourth embodiment of the present disclosure employs a high pass impedance inverter obtained by interchanging the capacitor and the inductor in each embodiment described above.

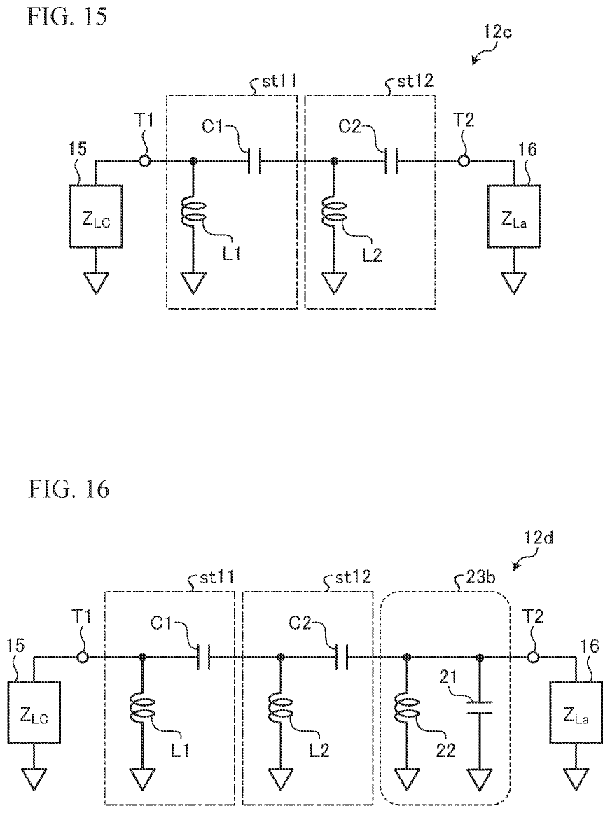

FIG. 15 is a diagram illustrating an impedance inverter 12c used in the power amplifier circuit according to the fourth embodiment. In FIG. 15, the two unit circuits, namely, unit circuits st11 and st12, are cascade-connected between the terminal T1 on the input side and the terminal T2 on the output side. That is, the impedance inverter 12c includes the plurality of cascade-connected unit circuits, namely, the unit circuits st11 and st12.

Focusing on the unit circuit st11, one end of the capacitor C1 is connected to the terminal T1 on the input side. The other end of the capacitor C1 is connected to one end of the capacitor C2 of the unit circuit st12. One end of the inductor L1 of the unit circuit st1 is connected between the capacitor C1 and the terminal T1. The other end of the inductor L1 is connected to the reference potential.

Focusing on the unit circuit st12, the one end of the capacitor C2 is connected to the other end of the capacitor C1. The other end of the capacitor C2 is connected to the terminal T2 on the output side. One end of the inductor L2 of the unit circuit st12 is connected between the capacitor C1 and the capacitor C2. The other end of the inductor L2 is connected to the reference potential.

Focusing on the unit circuit st11, when one of the inductor and the capacitor of the unit circuit st11 is defined as a first element (in this example, the capacitor C1) and the other is defined as a second element (in this example, the inductor L1), the first element included in the unit circuit st11 is connected in series to a first element (in this example, the capacitor C2) of the unit circuit st12, which is the adjacent unit circuit. Furthermore, the second element included in the unit circuit st11 is connected between one end of the first element of the same unit circuit st11 and the reference potential.

Focusing on the unit circuit st12, when one of the inductor and the capacitor of the unit circuit st12 is defined as a first element (in this example, the capacitor C2) and the other is defined as a second element (in this example, the inductor L2), the first element included in the unit circuit st12 is connected in series to a first element (in this example, the capacitor C1) of the unit circuit st11, which is the adjacent unit circuit. Furthermore, the second element included in the unit circuit st12 is connected between one end of the first element of the same unit circuit st12 and the reference potential.

Note that the phase is advanced by an effect of the impedance inverter 12c, and therefore, when the configuration illustrated in FIG. 15 is used, the phase of an input signal that is input to the carrier amplifier 1 needs to be delayed by 90 degrees and the phase of the peak amplifier 2 needs to be advanced relative to the carrier amplifier 1.

### Operations

The impedance inverter 12c illustrated in FIG. 15 can attain matching characteristics represented by the locus described with reference to FIG. 11. Using the impedance inverter 12c can improve the matching frequency band.

### Effects

Using the high pass impedance inverter according to this embodiment in the power amplifier circuit can attain a wider bandwidth in the power amplifier circuit.

### Fifth Embodiment

### Configuration

A power amplifier circuit according to a fifth embodiment of the present disclosure will now be described. In the power amplifier circuit according to the fifth embodiment of the present disclosure, a parallel resonance circuit is provided on the output side of the impedance inverter 12c described with reference to FIG. 15. FIG. 16 is a diagram illustrating an impedance inverter 12d used in the power amplifier circuit according to the fifth embodiment.

In FIG. 16, the two unit circuits, namely, the unit circuits st11 and st12, are cascade-connected. Furthermore, a parallel resonance circuit 23b is connected to the output side of the unit circuit st12. More specifically, the parallel resonance circuit 23b is connected between the capacitor C2 of the unit circuit st12 and the terminal T2 on the output side. The parallel resonance circuit 23b includes the inductor 22 and the capacitor 21. One end of the inductor 22 is electrically connected to the capacitor C2 and the other end thereof is connected to the reference potential. One end of the capacitor 21 is electrically connected to the capacitor C2 and the other end thereof is connected to the reference potential. That is, the parallel resonance circuit 23b is provided between a path on the output side of the unit circuit st12 and the reference potential.

Similarly to the impedance inverter 12b described with reference to FIG. 14, when the capacitor 21 and the inductor 22 enter a resonance state, this state appears to be a state in which the capacitor 21 or the inductor 22 is not connected. Therefore, when the capacitor 21 and the inductor 22 enter a resonance state, the impedance inverter 12d is in a state the same as the impedance inverter 12c illustrated in FIG. 15.

### Operations

When the capacitor 21 and the inductor 22 enter a resonance state in the parallel resonance circuit 23b, this state appears to be a state in which the capacitor 21 or the inductor 22 is not connected. Therefore, when the capacitor 21 and the inductor 22 enter a resonance state, the impedance inverter 12d is in a state the same as the impedance inverter 12c illustrated in FIG. 15.

### Effects

Using the impedance inverter 12d according to this embodiment in the power amplifier circuit can attain a wider bandwidth in the power amplifier circuit.

### Sixth Embodiment

### Configuration

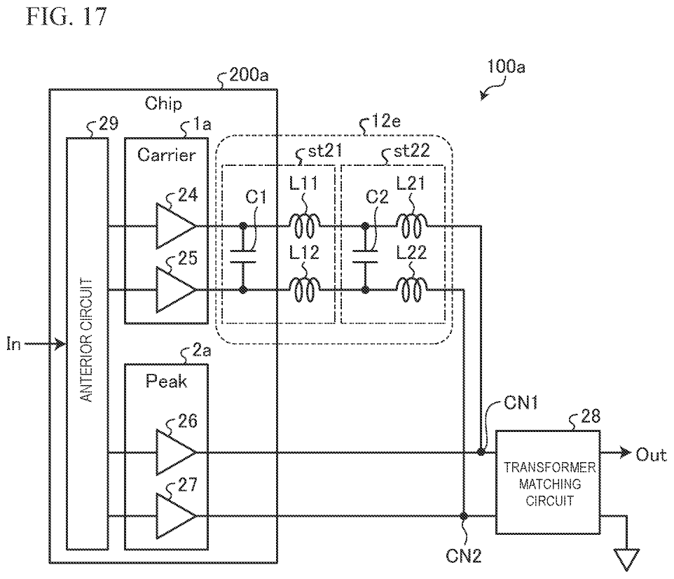

A power amplifier circuit according to a sixth embodiment of the present disclosure will now be described. The power amplifier circuit according to the sixth embodiment of the present disclosure employs a differential amplifier as a carrier amplifier 1a and a peak amplifier 2a. FIG. 17 is a diagram illustrating a power amplifier circuit 100a according to the sixth embodiment of the present disclosure.

In FIG. 17, the power amplifier circuit 100a includes an anterior circuit 29, the carrier amplifier 1a, which is a first amplifier, the peak amplifier 2a, which is a second amplifier, an impedance inverter 12e, and a transformer matching circuit 28.

The carrier amplifier 1a includes amplifier circuits 24 and 25 respectively including transistors that are driven by signals having phases different from each other by 180 degrees. That is, the amplifier circuits 24 and 25 constitute a pair of amplifier elements that differentially operate. Therefore, the carrier amplifier 1a includes the pair of amplifier elements that differentially operate. The peak amplifier 2a similarly includes amplifier circuits 26 and 27 respectively including transistors that differentially operate. That is, the amplifier circuits 26 and 27 constitute a pair of amplifier elements that differentially operate. Therefore, the peak amplifier 2a includes the pair of amplifier elements that differentially operate. Both outputs of the amplifier circuits 24 and 25 in the carrier amplifier 1a are input to the impedance inverter 12e.

The impedance inverter 12e has a differential configuration similarly to the carrier amplifier 1a and the peak amplifier 2a. The impedance inverter 12e includes two unit circuits, namely, unit circuits st21 and st22. The two unit circuits, namely, the unit circuits st21 and st22, are cascade-connected.

The unit circuit st21 includes the capacitor C1 connected between differential lines and inductors L11 and L12 connected in series to the respective differential lines. The unit circuit st22 includes the capacitor C2 connected between the differential lines and inductors L21 and L22 connected in series to the respective differential lines.

One end of the capacitor C1 of the unit circuit st21 is connected to the output of the amplifier circuit 24. The other end of the capacitor C1 is connected to the output of the amplifier circuit 25. One end of the inductor L11 is connected to the output of the amplifier circuit 24 and the one end of the capacitor C1. The other end of the inductor L11 is connected to one end of the capacitor C2 of the unit circuit st22 and one end of the inductor L21 thereof. One end of the inductor L12 is connected to the output of the amplifier circuit 25 and the other end of the capacitor C1. The other end of the inductor L12 is connected to the other end of the capacitor C2 of the unit circuit st22 and one end of the inductor L22 thereof. The other end of the inductor L21 is connected to the output of the amplifier circuit 26 at a connecting node CN1. The other end of the inductor L22 is connected to the output of the amplifier circuit 27 at a connecting node CN2.

Focusing on the unit circuit st21, when one of the pair of inductors and the capacitor of the unit circuit st21 is defined as a first element (in this example, the inductors L11 and L12) and the other is defined as a second element (in this example, the capacitor C1), the unit circuit st21 includes a pair of first elements (in this example, the inductors L11 and L12) so as to correspond to the pair of amplifier elements (the amplifier circuits 24 and 25). The first elements included in the unit circuit st21 are connected in series to first elements (in this example, the inductors L21 and L22) of the unit circuit st22, which is the adjacent unit circuit. Furthermore, the second element included in the unit circuit st21 is connected between one end of one first element of the pair of first elements included in the same unit circuit and one end of the other first element thereof. That is, the second element is connected between one end of one first element of the pair of first elements included in the same unit circuit and one end of the other first element thereof, each one end being an end closer to the carrier amplifier 1a (that is, the first amplifier).

Focusing on the unit circuit st22, when one of the pair of inductors and the capacitor of the unit circuit st22 is defined as a first element (in this example, the inductors L21 and L22) and the other is defined as a second element (in this example, the capacitor C2), the unit circuit st22 includes a pair of first elements (in this example, the inductors L21 and L22) so as to correspond to the pair of amplifier elements (the amplifier circuits 24 and 25). The first elements included in the unit circuit st22 are connected in series to first elements (in this example, the inductors L11 and L12) of the unit circuit st21, which is the adjacent unit circuit. Furthermore, the second element included in the unit circuit st22 is connected between one end of one first element of the pair of first elements included in the same unit circuit and one end of the other first element thereof. That is, the second element is connected between one end of one first element of the pair of first elements included in the same unit circuit and one end of the other first element thereof, each one end being an end closer to the carrier amplifier 1a (that is, the first amplifier).

The anterior circuit 29 includes a phase shifter for delaying in advance the phase of a signal that is input to the peak amplifier 2a by 90 degrees compared to that of a signal that is input to the carrier amplifier 1a, a driver stage, and so on. The transformer matching circuit 28 is a matching circuit on the output side.

In this embodiment, the anterior circuit 29, the carrier amplifier 1a, the peak amplifier 2a, and the capacitor C1 of the impedance inverter 12e are formed on one semiconductor chip 200a.

### Operations

This embodiment can also be considered to employ a configuration in which a capacitor on a side on which the impedance is low is removed. Therefore, the locus described with reference to FIG. 11 is drawn, and a wider bandwidth can be attained in the power amplifier circuit as described with reference to FIG. 12.

### Effects

This embodiment can improve the matching frequency band for the Doherty power amplifier circuit that differentially operates.

### Seventh Embodiment

### Configuration

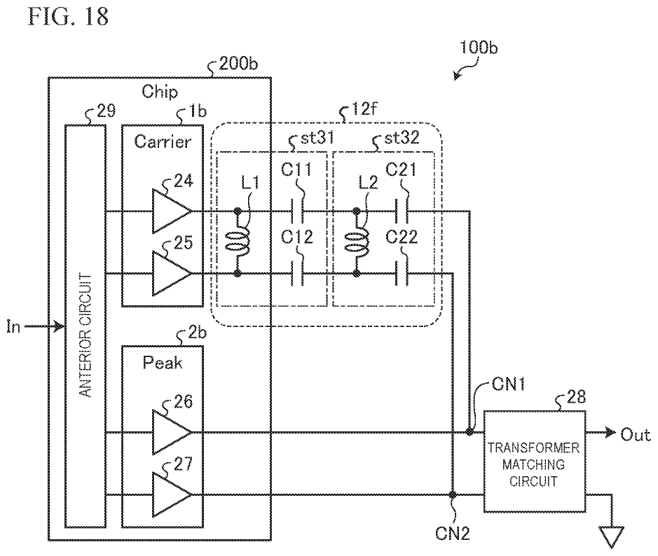

A power amplifier circuit according to a seventh embodiment of the present disclosure will now be described. FIG. 18 is a diagram illustrating a power amplifier circuit 100b according to the seventh embodiment of the present disclosure. The power amplifier circuit 100b according to the seventh embodiment of the present disclosure employs a differential amplifier as the carrier amplifier 1a and the peak amplifier 2a as in the sixth embodiment. The power amplifier circuit according to the seventh embodiment of the present disclosure is different from the sixth embodiment in the configuration of an impedance inverter 12f.

The impedance inverter 12f is a high pass impedance inverter obtained by interchanging the capacitors and the inductors of the impedance inverter 12e described with reference to FIG. 17. The impedance inverter 12f has a differential configuration similarly to the carrier amplifier 1b and the peak amplifier 2b. The impedance inverter 12f includes two unit circuits, namely, unit circuits st31 and st32. The two unit circuits, namely, the unit circuits st31 and st32, are cascade-connected.

The unit circuit st31 includes the inductor L1 connected between differential lines and capacitors C11 and C12 connected in series to the respective differential lines. The unit circuit st32 includes the inductor L2 connected between the differential lines and the capacitors C21 and C22 connected in series to the respective differential lines.

One end of the inductor L1 of the unit circuit st31 is connected to the output of the amplifier circuit 24. The other end of the inductor L1 is connected to the output of the amplifier circuit 25. One end of the capacitor C11 is connected to the output of the amplifier circuit 24 and the one end of the inductor L1. The other end of the capacitor C11 is connected to one end of the capacitor C21 of the unit circuit st32 and one end of the inductor L2 thereof. One end of the capacitor C12 is connected to the output of the amplifier circuit 25 and the other end of the inductor L1. The other end of the capacitor C12 is connected to one end of the capacitor C22 of the unit circuit st32 and the other end of the inductor L2 thereof. The other end of the capacitor C21 is connected to the output of the amplifier circuit 26 at the connecting node CN1. The other end of the capacitor C22 is connected to the output of the amplifier circuit 27 at the connecting node CN2.

Focusing on the unit circuit st31, when one of the inductor and the pair of capacitors of the unit circuit st31 is defined as a first element (in this example, the capacitors C11 and C12) and the other is defined as a second element (in this example, the inductor L1), the unit circuit st31 includes a pair of first elements (in this example, the capacitors C11 and C12) so as to correspond to the pair of amplifier elements (the amplifier circuits 24 and 25). The first elements included in the unit circuit st31 are connected in series to first elements (in this example, the capacitors C21 and C22) of the unit circuit st32, which is the adjacent unit circuit. Furthermore, the second element included in the unit circuit st31 is connected between one end of one first element of the pair of first elements included in the same unit circuit and one end of the other first element thereof. That is, the second element is connected between one end of one first element of the pair of first elements included in the same unit circuit and one end of the other first element thereof, each one end being an end closer to the carrier amplifier 1b (that is, the first amplifier).

Focusing on the unit circuit st32, when one of the inductor and the pair of capacitors of the unit circuit st32 is defined as a first element (in this example, the capacitors C21 and C22) and the other is defined as a second element (in this example, the inductor L2), the unit circuit st32 includes a pair of first elements (in this example, the capacitors C21 and C22) so as to correspond to the pair of amplifier elements (the amplifier circuits 24 and 25). The first elements included in the unit circuit st32 are connected in series to first elements (in this example, the capacitors C11 and C12) of the unit circuit st31, which is the adjacent unit circuit. Furthermore, the second element included in the unit circuit st32 is connected between one end of one first element of the pair of first elements included in the same unit circuit and one end of the other first element thereof. That is, the second element is connected between one end of one first element of the pair of first elements included in the same unit circuit and one end of the other first element thereof, each one end being an end closer to the carrier amplifier 1b (that is, the first amplifier).

Note that the phase is advanced by an effect of the impedance inverter 12f, and therefore, when the configuration illustrated in FIG. 17 is used, the phase of an input signal that is input to the carrier amplifier 1b needs to be delayed by 90 degrees and the phase of the peak amplifier 2b needs to be advanced relative to the carrier amplifier 1b. Such an adjustment of the phase can be made by the anterior circuit 29.

In this embodiment, the anterior circuit 29, the carrier amplifier 1b, the peak amplifier 2b, and the inductor L1 of the impedance inverter 12f are formed on one semiconductor chip 200b.

### Operations

This embodiment can also be considered to employ a configuration in which a capacitor on a side on which the impedance is low is removed. Therefore, the locus described with reference to FIG. 11 is drawn, and a wider bandwidth can be attained in the power amplifier circuit as described with reference to FIG. 12.

### Effects

This embodiment can improve the matching frequency band for the Doherty power amplifier circuit that differentially operates.

### Eighth Embodiment

### Configuration

A power amplifier circuit according to an eighth embodiment of the present disclosure will now be described. The power amplifier circuit according to each embodiment described above combines the current of an output of the carrier amplifier and the current of an output of the peak amplifier together at the connecting node and outputs the combined output. In contrast, the voltages of both outputs are combined together and output in this embodiment.

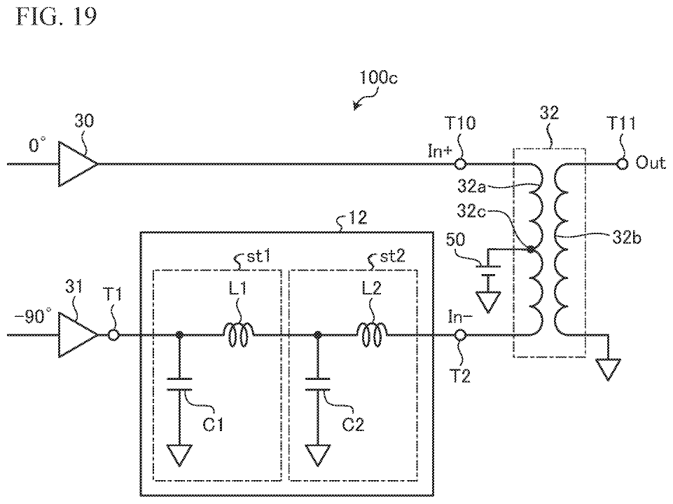

FIG. 19 is a diagram illustrating a power amplifier circuit 100c according to the eighth embodiment of the present disclosure. In FIG. 19, the power amplifier circuit 100c includes a carrier amplifier 30, a peak amplifier 31, a transformer matching circuit 32, and the impedance inverter 12.

The output end of the carrier amplifier 30 is connected to a terminal T10. The output end of the peak amplifier 31 is connected to the terminal T1.

The impedance inverter 12 is an asymmetrical impedance inverter described with reference to FIG. 9 and FIG. 10. The impedance inverter 12 is connected between the terminal T1 and the terminal T2.

The transformer matching circuit 32 includes a primary inductor 32a and a secondary inductor 32b. One end of the primary inductor 32a is connected to the terminal T10 and the other end thereof is connected to the terminal T2 on the output side of the impedance inverter 12. One end of the secondary inductor 32b is connected to a terminal T11 on the output side and the other end thereof is connected to the reference potential. A midpoint 32c of the primary inductor 32a is connected to the reference potential with a DC voltage 50 interposed therebetween. The primary inductor 32a and the secondary inductor 32b are magnetically coupled to each other.

### Operations

Suppose that the output impedance of the peak amplifier 31 is sufficiently high, the impedance at the terminal T2 on a side connected to the transformer matching circuit 32 becomes close to 0 due to the impedance inverter 12, and the impedance inverter 12 can be considered to be a voltage source. Therefore, an output of the impedance inverter 12 can be combined in series with an output of the carrier amplifier 30 by the transformer matching circuit 32.

In the power amplifier circuit 100c of this embodiment, the phase of an input of the peak amplifier 31 is delayed by 90 degrees (that is, −90°) relative to an input of the carrier amplifier 30. Furthermore, the phase of an output of the peak amplifier 31 is delayed by the impedance inverter 12 by 90 degrees. Therefore, the output of the peak amplifier 31 is delayed by 180 degrees in total relative to the output of the carrier amplifier 30. Accordingly, the phase difference between a signal In+ at the terminal T10 on the input side of the transformer matching circuit 32 and a signal In− at the terminal T2 on the input side of the transformer matching circuit 32 becomes 180 degrees. That is, differential signals are applied to the input side of the transformer matching circuit 32 and a single-end signal is output from the terminal T11 on the output side of the transformer matching circuit 32.

### Effects

This embodiment can improve the matching frequency band for the voltage-combining Doherty power amplifier circuit.

### Ninth Embodiment

### Configuration

A power amplifier circuit according to a ninth embodiment of the present disclosure will now be described. The power amplifier circuit according to each embodiment described above combines the current of an output of the carrier amplifier and the current of an output of the peak amplifier together at the connecting node and outputs the combined output. In contrast, the voltages of both outputs are combined together and output in this embodiment.

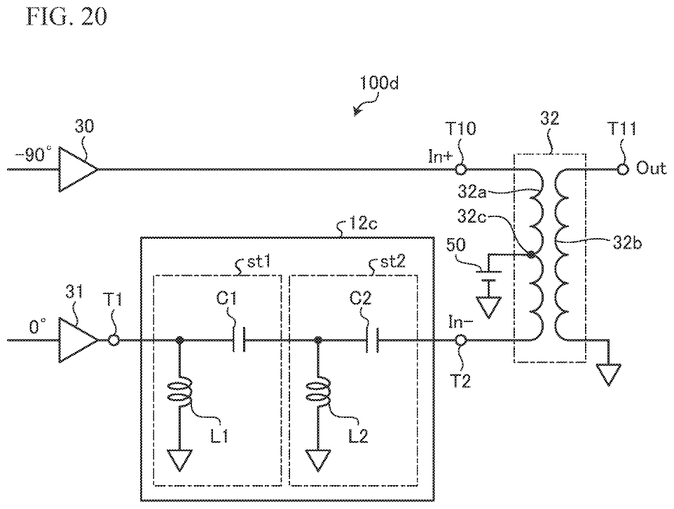

FIG. 20 is a diagram illustrating a power amplifier circuit 100d according to the ninth embodiment of the present disclosure. In FIG. 20, the power amplifier circuit 100d includes the carrier amplifier 30, the peak amplifier 31, the transformer matching circuit 32, and the impedance inverter 12c.

In the power amplifier circuit 100d of this embodiment, the impedance inverter 12c described with reference to FIG. 15 is used instead of the impedance inverter 12 in FIG. 19.

### Operations

Suppose that the output impedance of the peak amplifier 31 is sufficiently high, the impedance at the terminal T2 on a side connected to the transformer matching circuit 32 becomes close to 0 due to the impedance inverter 12c, and the impedance inverter 12c can be considered to be a voltage source. Therefore, an output of the impedance inverter 12c can be combined in series with an output of the carrier amplifier 30 by the transformer matching circuit 32.

In the power amplifier circuit 100d of this embodiment, the phase of an input of the carrier amplifier 30 is delayed by 90 degrees (that is, −90°) relative to an input of the peak amplifier 31. Furthermore, the phase of an output of the peak amplifier 31 is delayed by the impedance inverter 12c by 90 degrees. Therefore, the output of the peak amplifier 31 is delayed by 180 degrees in total relative to the output of the carrier amplifier 30. Accordingly, the phase difference between a signal In+ at the terminal T10 on the input side of the transformer matching circuit 32 and a signal In− at the terminal T2 on the input side of the transformer matching circuit 32 becomes 180 degrees. That is, differential signals are applied to the input side of the transformer matching circuit 32 and a single-end signal is output from the terminal T11 on the output side of the transformer matching circuit 32.

### Effects

This embodiment can improve the matching frequency band for the voltage-combining Doherty power amplifier circuit.

What is claimed is:

1. A power amplifier circuit comprising:
a first amplifier;
a second amplifier; and
an impedance inverter configured to delay an output of the first amplifier by a time equivalent to ¼ of a wavelength of a transmission line,
wherein the power amplifier circuit is configured to combine the output of the first amplifier delayed by the impedance inverter and an output of the second amplifier, and to output a combined output,
wherein the impedance inverter comprises a plurality of unit circuits, each unit circuit comprising a first element and a second element, the first element being one of an inductor and a capacitor and the second element being the other of the inductor and the capacitor,
wherein the plurality of unit circuits are cascade-connected to an output side of the first amplifier,
wherein the first element of each unit circuit is connected in series to the first element of an adjacent unit circuit, and
wherein the second element of each unit circuit is connected between a reference potential and the end of the first element of that unit circuit that is closest to the first amplifier.

2. The power amplifier circuit according to claim 1,
wherein the first amplifier and the second amplifier constitute a Doherty amplifier circuit, and
wherein the first amplifier is one of a carrier amplifier and a peak amplifier of the Doherty amplifier circuit, and the second amplifier is the other of the carrier amplifier and the peak amplifier of the Doherty amplifier circuit.

3. The power amplifier circuit according to claim 1, further comprising:
a parallel resonance circuit that is between a path on an output side of the plurality of unit circuits and the reference potential.

4. A power amplifier circuit comprising:
a first amplifier;
a second amplifier; and
an impedance inverter configured to delay an output of the first amplifier by a time equivalent to ¼ of a wavelength of a transmission line,
wherein the power amplifier circuit is configured to combine the output of the first amplifier delayed by the impedance inverter and an output of the second amplifier, and to output a combined output,
wherein the first amplifier and the second amplifier each include a pair of amplifier elements that operate differentially,
wherein the impedance inverter comprises a plurality of unit circuits, each unit circuit comprising a pair of first elements corresponding to the pair of amplifier elements and a second element, the pair of first elements being one of a pair of inductors or capacitors and the second element being the other of the inductor and the capacitor,
wherein the plurality of unit circuits are cascade-connected to an output side of the first amplifier,
wherein the pair of first elements of each unit circuit are connected in series to the pair of first elements of an adjacent unit circuit, and
wherein the second element of each unit circuit is connected between a first end of a first of the pair of first elements of that unit circuit, and a first end of a second of the pair of first elements of that unit circuit, each first end being the end of the first element that is closest to the first amplifier.

5. The power amplifier circuit according to claim 4,
wherein the first amplifier and the second amplifier constitute a Doherty amplifier circuit, and
wherein the first amplifier is one of a carrier amplifier and a peak amplifier of the Doherty amplifier circuit, and the second amplifier is the other of the carrier amplifier and the peak amplifier of the Doherty amplifier circuit.
